(19) United States
(12) Patent Application Publication
(10) Pub. No.: US 2002/0175803 A1
(43) Pub. Date: Nov. 28, 2002

(54) Vehicle-mounted magnetoresistive sensor element

(75) Inventors: Yuji Kawano, Tokyo (JP); Motohisa Taguchi, Tokyo (JP); Ikuya Kawakita, Tokyo (JP); Tatsuya Fukami, Tokyo (JP)

Correspondence Address: SUGHRUE,MION, ZINN, MACPEAK & SEAS, 2100 Pennsylvania Avenue, N.W., Washington, DC, 20037, US

(73) Assignee: MITSUBISHI DENKI KABUSHIKI KAISHA

(21) Appl. No.: 09/996,580

(22) Filed: Nov. 30, 2001

(30) Foreign Application Priority Data
May 28, 2001 (JP) 2001-158903

(51) Int. Cl. H01L 43/00

(52) U.S. Cl. 338/32 R

(57) ABSTRACT

A vehicle-mounted magnetoresistive sensor element includes plural plies of a magnetic layer and plural plies of a nonmagnetic layer, the magnetic layer and the nonmagnetic layer are alternately laminated with each other, the magnetic layer mainly contains Ni, Fe and Co, and the nonmagnetic layer mainly contains Cu, in which the magnetic layer has a composition represented by the following formula: Ni_{(1-x-y)}Fe_{y}Coₓ, where x and y satisfy the following conditions: x≧0.7, y≦0.3 and (1−x−y)≦0.15, the nonmagnetic layer has a composition represented by the following formula: Cu_{z}Al_{(1-z)}, where A is an additional element other than Cu, and z≧0.9; the thickness tm (angstrom) of the magnetic layer and the thickness tn (angstrom) of the nonmagnetic layer satisfy the following conditions: 10<tm<25; and 18<tn<25; and, when a guaranteed storage temperature of the magnetoresistive sensor element is T° C., the magnetoresistive sensor element has been previously subjected to heat treatment at a temperature equal to or higher than T° C.

This application is based on Application No. 2001-158903, filed in Japan on May 28, 2001, the contents of which are hereby incorporated by reference.

### BACKGROUND OF THE INVENTION

1. Field of the Invention

The present invention relates to a sensor element for detecting, for example, the number of revolutions or angle of rotation of a rotating article. Specifically, it relates to a magnetoresistive sensor element which has a laminate structure composed of magnetic layers and nonmagnetic layers, detects a magnetic field induced by the rotating article and converts the detected magnetic field to an electric signal. More specifically, the present invention relates to a vehicle-mounted magnetoresistive sensor element which must be stored or must operate under high temperature conditions.

2. Description of the Related Art

Semiconductor Hall elements and anisotropic magnetoresistive (AMR) elements have been used as electromagnetic conversion elements that detect a magnetic field and converts the same into an electric signal. Additionally, giant magnetoresistive (GMR) elements have a sensitivity higher than these elements and have recently received attention.

The semiconductor Hall element exhibits no hysteresis in electromagnetic conversion characteristics and exhibits satisfactory characteristics as sensors but has a lower sensitivity than the other sensor elements. The AMR elements has a higher sensitivity than the semiconductor Hall element but exhibits a small magnetic field range (saturation magnetic field) that yields a change in electrical resistance and is susceptible to a disturbance magnetic field. However, these elements have no problem in storage and operation under high temperature conditions and have been used as vehicle-mounted elements.

The GMR element exhibits a magnetoresistance ratio (MR ratio) higher by an order of magnitude than the AMR element. However, such conventional GMR elements cannot simultaneously have satisfactory sensitivity and heat tolerance. Specifically, the GMR elements cannot significantly have satisfactory heat tolerance and attempts have been exclusively made to achieve a small hysteresis. Accordingly, the GMR element has been practically used as a magnetic head for hard disk drive immediately after the discovery of the giant magnetoresistive effect but has not been practically used as a vehicle-mounted sensor element.

The heat tolerance of the GMR element has been reported by D. Wang et al. (D. Wang, J. Anderson, J. M. Daughton, IEEE TRANSACTIONS ON MAGNETICS, Vol. 33, No. 5, pp. 3520-3522, 1997). A GMR film reported in this report is not suitable as a vehicle-mounted magnetoresistive sensor element, since the report fails to discuss a relationship between the saturation magnetic field and the operation under high temperature conditions. Specifically, this GMR film exhibits a low saturation magnetic field, and is supposed to have an insufficient sensitivity, i.e., an insufficient output, under high temperature conditions when the operating magnetic field of the film is set at a sufficient magnitude as a vehicle-mounted element, although the high-temperature characteristics of the film are not described in the report. Such vehicle-mounted elements must be heat tolerance so that the characteristics of the elements are not deteriorated by storage under high temperature conditions and must have satisfactory performance characteristics under high temperature conditions such that the elements operate under high temperature conditions without problems.

These vehicle-mounted sensor elements are used, for example, for engine control or for transmission control, and require to have a higher sensitivity because of emission control in recent years. However, the semiconductor Hall element and AMR element do not have a sufficient sensitivity and demands have been made to provide sensor elements having a higher sensitivity.

In contrast, the GMR element is expected to have a high sensitivity. However, the GMR element readily shows changes in characteristics under high temperature conditions, since it has a laminated structure composed of a magnetic layer and a nonmagnetic layer, and each layer constituting the element has a very small thickness, thus inviting diffusion in interface. Additionally, a low hysteresis with a relatively high saturation magnetic field is required to yield sufficient output even under high temperature conditions. The conventional GMR element therefore cannot be significantly applied as a vehicle-mounted sensor element which must have highly stable characteristics under high temperature conditions.

### SUMMARY OF THE INVENTION

Accordingly, an object of the present invention is to provide a highly sensitive GMR element that is resistant to a disturbance magnetic field in storage and operation under high temperature conditions. Specifically, the object of the present invention is to provide a GMR element that has satisfactorily stable characteristics under high temperature conditions over the long term as a result of an appropriate heat treatment and is suitable as a vehicle-mounted sensor element.

Specifically, the present invention provides, in an aspect, a vehicle-mounted magnetoresistive sensor element including plural plies of a magnetic layer and plural plies of a nonmagnetic layer, the magnetic layer and the nonmagnetic layer is alternately laminated with each other, the magnetic layer mainly contains Ni, Fe and Co, and the nonmagnetic layer mainly contains Cu, in which the magnetic layer has a composition represented by the following formula: Ni_{(1-x-y)}Fe_{y}Coₓ, where x and y satisfy the following conditions: x≧0.7, y≦0.3 and (1−x−y)≦0.15, the nonmagnetic layer has a composition represented by the following formula: Cu_{z}A_{(1-z)}, where A is an additional element other than Cu, and z≧0.9, the thickness tm (angstrom) of the magnetic layer and the thickness tn (angstrom) of the nonmagnetic layer satisfy the following conditions: 10<tm<25; and 18<tn<25, and, when the guaranteed storage temperature of the magnetoresistive sensor element is T° C., the magnetoresistive sensor element has been previously subjected to heat treatment at a temperature equal to or higher than T° C.

Preferably, when a unit composed of a laminate of one ply of the magnetic layer and one ply of the nonmagnetic layer is defined as a repeating constitutional unit, the number N of the repeating constitutional units in the magnetoresistive sensor element satisfies the following condition: 10≦N≦40.

The vehicle-mounted magnetoresistive sensor element preferably further includes a substrate and a buffer layer, which buffer layer is sandwiched between the substrate and the magnetic layer or is sandwiched between the substrate and the nonmagnetic layer, in which the thickness tb (angstrom) of the buffer layer satisfies the following condition: 10<tb<80.

In the vehicle-mounted magnetoresistive sensor element, the heat treatment is preferably performed at a temperature equal to or higher than (T+50)° C.

In the vehicle-mounted magnetoresistive sensor element just mentioned above, the heat treatment is preferably performed at a temperature equal to or higher than 200° C. and lower than or equal to 300° C.

### BRIEF DESCRIPTION OF THE DRAWINGS

FIG. 1 is a sectional view of a vehicle-mounted magnetoresistive sensor element according to an embodiment of the present invention;

FIGS. 2a and 2b are diagrams showing electromagnetic conversion characteristics (magnetoresistance curve) of a vehicle-mounted magnetoresistive sensor element according to the invention before and after heat treatment in Example 1;

FIG. 3 is a diagram showing changes in magnetoresistance ratio (MR ratio) of vehicle-mounted magnetoresistive sensor elements according to Examples 1 to 3 and Comparative Examples 1 to 3, after 500-hour storage at temperatures ranging from 100° C. to 200° C., assumed range of ambient temperatures, as compared with the magnetoresistance ratio (MR ratio) before storage;

FIG. 4 is a diagram showing a change in magnetoresistance ratio (MR ratio) when the vehicle-mounted magnetoresistive sensor element according to Example 1 is subjected to heat treatment at 200° C. or 250° C., higher than the ambient temperature, and is then stored at 170° C. for 500 hours;

FIG. 5 is a diagram showing a change in the minimum of electric resistance of the vehicle-mounted magnetoresistive sensor element according to Example 1 after the same treatment as in FIG. 4;

FIG. 6 is a diagram showing changes in magnetoresistance ratio (MR ratio) of vehicle-mounted magnetoresistive sensor elements according to Examples 1 and 3 to 5 and Comparative Examples 1 to 3 after heat treatment at temperatures ranging from 200° C. to 300° C. for 12 hours, as compared with the magnetoresistance ratio (MR ratio) before heat treatment; and

FIG. 7 is a diagram showing the sensitivities of the vehicle-mounted magnetoresistive sensor elements according to Examples 6 and 7 as measured at room temperature and at a high temperature (150° C.).

### DETAILED DESCRIPTION OF THE INVENTION

Specifically, the invented vehicle-mounted magnetoresistive sensor element utilizes a GMR element and specifies the compositions and thickness of constitutional magnetic layer and nonmagnetic layer to the aforementioned ranges. The resulting sensor element can therefore set its operating magnetic field at a magnetic field higher than a disturbance magnetic field and can have a high sensitivity. Additionally, the sensor element exhibits less change in characteristics in storage and operation under high temperature conditions. More specifically, the combination use of Co and Cu can yield a highly heat resistant laminate structure, and the addition of Fe or Ni to Co can improve the sensitivity at the operating magnetic field. Additionally, the selection of the optimum thickness of individual layers and the optimum number of laminate units can avoid deterioration in characteristics even under high temperature conditions.

This GMR element can be subjected to heat treatment at high temperatures and can be subjected to heat treatment at a temperature higher than the guaranteed storage temperature T° C. of the sensor element to invite a specific initial change to thereby stabilize the characteristics of the sensor element.

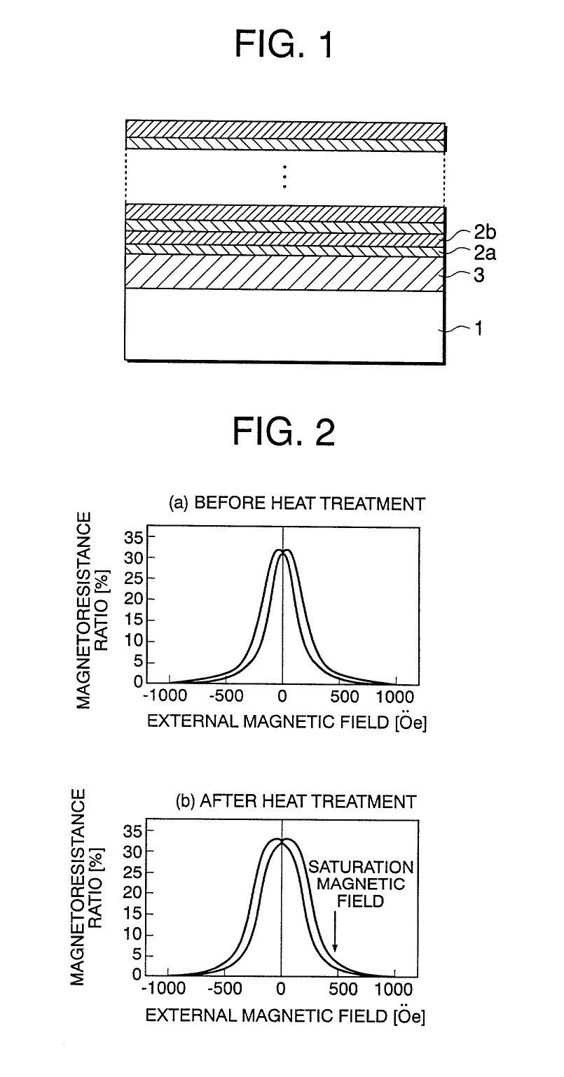

FIG. 1 is a sectional view of a vehicle-mounted magnetoresistive sensor element according to an embodiment of the present invention. The sensor element is a GMR element and is composed of, for example, Si substrate 1 with a thermal oxide SiO₂ film, and magnetic layer 2a and nonmagnetic layer 2b formed on substrate 1, and magnetic layer 2a and nonmagnetic layer 2b are laminated with each other as shown in FIG. 1.

Buffer layer 3 is previously formed between substrate 1 and magnetic layer 2a. Substrate 1 may be a single Si crystal substrate; films of SiO₂, PSG (phosphosilicate glass), and other oxides, films of SiNₓ and other nitrides, and films of Si-based polymers and other organic resins, as well as the Si substrate with thermal oxide Sio₂ film. Buffer layer 3 may not be formed in some types of substrate 1, but is preferably formed to yield stable characteristics. Buffer layer 3 is preferably composed of the same material with that of magnetic layer 2a.

### EXAMPLES

The present invention will be illustrated in further detail with reference to several invented examples and comparative examples below, which are not intended to limit the scope of the invention.

### Example 1

A GMR element according to the present example has a structure as shown in FIG. 1 and the materials and atomic compositional ratios of individual layers are as follows. Magnetic layer 2a is composed of Fe_{0.1}Cu_{0.9}, nonmagnetic layer 2b is composed of Cu, and buffer layer 3 has an atomic compositional ratio of Fe_{0.1}Co_{0.9} the same as in magnetic layer 2a. Magnetic layer 2a, nonmagnetic layer 2b and buffer layer 3 each have a thickness of 15 angstroms, 21 angstroms, and 50 angstroms, respectively. When a laminate structure composed of one ply of magnetic layer 2a and one ply of nonmagnetic layer 2b is defined as a repeating constitutional unit, the number N of the repeating constitutional units in the sensor element is 20. These layers can be formed, for example, by vapor deposition, molecular beam epitaxy (MBE) or sputtering, of which sputtering is preferred from the viewpoints of the characteristics and productivity of the resulting sensing element.

This laminate film is subjected to photolithographic patterning by, for example, dry etching. The width of patterning is, for example, from 1 μm to 30 μm. A protective film such as an Si₃N₄ film is then formed on the patterned film by, for example, sputtering or chemical vapor deposition (CVD) to thereby protect the patterned film and the resulting structure is subjected to heat treatment. The heat treatment is performed for example at 250° C. for 12 hours.

FIGS. 2A and 2B are diagrams showing electromagnetic conversion characteristics (magnetoresistance curve) of the GMR element according to Example 1 before and after heat treatment. As a sensor, the greater the magnetoresistance ratio (MR ratio) is and the smaller the hysteresis in a range of operating magnetic field is, the higher the sensitivity is. The GMR element according to Example 1 exhibits a slightly changed shape of the magnetoresistance curve before and after heat treatment. This change is predominantly due to decrease in the minimum of electric resistance and due to increased magnetoresistance ratio (MR ratio). The GMR element shows neither decreased MR ratio nor increased hysteresis as in conventional GMR elements. Specifically, the invented GMR element has characteristics that are resistant to heat treatment at high temperatures and rather exhibits a higher sensitivity after heat treatment than that before heat treatment. The GMR element exhibits a saturation magnetic field of about 450 Oersteds. The operating magnetic field of the sensor element can be selected within a range from 100 Oersteds to 400 Oersteds, within which the magnetoresistance curve (MR curve) shows satisfactory linearity and the element can output satisfactory signals. The term “saturation magnetic field” as used herein means the magnitude of the magnetic field at a point where the integral of magnetoresistance ratio (MR ratio) occupies 90% of the total magnetoresistance ratio (MR ratio) in the magnetoresistance curve (MR curve) of GMR element as shown in FIG. 2B.

### Example 2

A GMR element according to the present example has a structure as shown in FIG. 1 and the materials and atomic compositional ratios of individual layers are as follows. Magnetic layer 2a is composed of Fe_{0.2}Co_{0.8}, nonmagnetic layer 2b is composed of Cu and buffer layer 3 is composed of Fe_{0.2}Co_{0.8} the same as in magnetic layer 2a. Magnetic layer 2a, nonmagnetic layer 2b and buffer layer 3 each have a thickness of 15 angstroms, 21 angstroms, and 50 angstroms, respectively. The number N of the repeating constitutional units in the GMR element is 25.

In the same manner as in Example 1, this film is patterned, followed by the formation of a protective film such as an Si₃N₄ film thereon and heat treatment at 250° C. for 12 hours.

### Example 3

A GMR element according to the present example has a structure as shown in FIG. 1 and the materials and atomic compositional ratios of individual layers are as follows. Magnetic layer 2a is composed of Ni_{0.12}Fe_{0.08}Co_{0.80}, nonmagnetic layer 2b is composed of Cu, and buffer layer 3 is composed of Ni_{0.12}Fe_{0.08}Co_{0.80} the same as in magnetic layer 2a. Magnetic layer 2a, nonmagnetic layer 2b and buffer layer 3 each have a thickness of 18 angstroms, 21 angstroms, and 50 angstroms, respectively. The number N of the repeating constitutional units in the GMR element is 30.

In the same manner as in Example 1, this film is patterned, followed by the formation of a protective film such as an Si₃N₄ film thereon and heat treatment at 250° C. for 12 hours.

### Example 4

A GMR element according to the present example has a structure as shown in FIG. 1 and the materials and atomic compositional ratios of individual layers are as follows. Magnetic layer 2a is composed of Fe_{0.1}Co_{0.9}, nonmagnetic layer 2b is composed of Cu, and buffer layer 3 is composed of Fe_{0.1}Co_{0.9} the same as in magnetic layer 2a. Magnetic layer 2a, nonmagnetic layer 2b and buffer layer 3 each have a thickness of 20 angstroms, 21 angstroms, and 50 angstroms, respectively. The number N of the repeating constitutional units in the GMR element is 20.

In the same manner as in Example 1, this film is patterned, followed by the formation of a protective film such as an Si₃N₄ film thereon and heat treatment at 250° C. for 12 hours.

### Example 5

A GMR element according to the present example has a structure as shown in FIG. 1 and the materials and atomic compositional ratios of individual layers are as follows. Magnetic layer 2a is composed of Fe_{0.1}Co_{0.9}, nonmagnetic layer 2b is composed of Cu, and buffer layer 3 is composed of Fe_{0.1}Co_{0.9} the same as in magnetic layer 2a. Magnetic layer 2a, nonmagnetic layer 2b and buffer layer 3 each have a thickness of 15 angstroms, 23 angstroms, and 50 angstroms, respectively. The number N of the repeating constitutional units in the GMR element is 20.

In the same manner as in Example 1, this film is patterned, followed by the formation of a protective film such as an Si₃N₄ film thereon and heat treatment at 250° C. for 12 hours.

Comparative examples corresponding to the invented examples above will be described below.

### Comparative Example 1

A GMR element according to the present comparative example has a structure as shown in FIG. 1 and the materials and atomic compositional ratios of individual layers are as follows. Magnetic layer 2a is composed of Fe_{0.6}Co_{0.4}, nonmagnetic layer 2b is composed of Cu, and buffer layer 3 is composed of Fe_{0.6}Co_{0.4} the same as in magnetic layer 2a. Magnetic layer 2a, nonmagnetic layer 2b and buffer layer 3 each have a thickness of 15 angstroms, 21 angstroms, and 50 angstroms, respectively. The number N of the repeating constitutional units in the GMR element is 20.

### Comparative Example 2

A GMR element according to the present comparative example has a structure as shown in FIG. 1 and the materials and atomic compositional ratios of individual layers are as follows. Magnetic layer 2a is composed of Ni_{0.15}Fe_{0.20}Co_{0.65}, nonmagnetic layer 2b is composed of Cu, and buffer layer 3 is composed of Ni_{0.15}Fe_{0.20}Co_{0.6} the same as in magnetic layer 2a. Magnetic layer 2a, nonmagnetic layer 2b and buffer layer 3 each have a thickness of 15 angstroms, 21 angstroms, and 50 angstroms, respectively. The number N of the repeating constitutional units in the GMR element is 30.

### Comparative Example 3

A GMR element according to the present comparative example has a structure as shown in FIG. 1 and the materials and atomic compositional ratios of individual layers are as follows. Magnetic layer 2a is composed of Fe_{0.1}Co_{0.9}, nonmagnetic layer 2b is composed of Cu, and buffer layer 3 is composed of Fe_{0.1}Co_{0.9} the same as in magnetic layer 2a. Magnetic layer 2a, nonmagnetic layer 2b and buffer layer 3 each have a thickness of 10 angstroms, 21 angstroms, and 50 angstroms, respectively. The number N of the repeating constitutional units in the GMR element is 20.

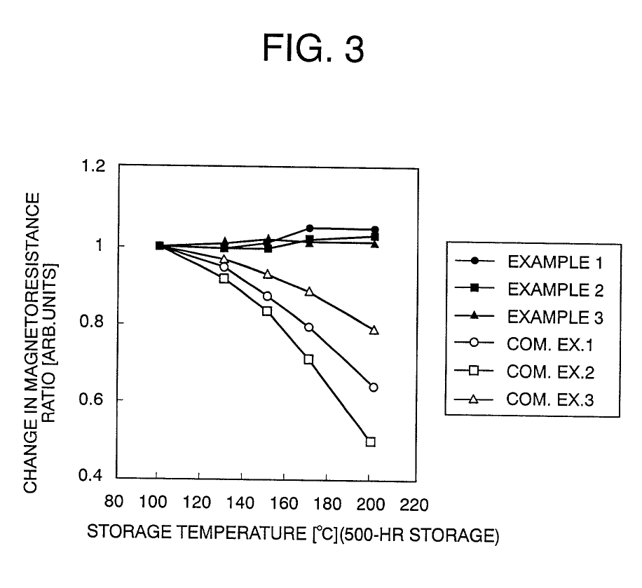

FIG. 3 is a diagram showing changes in magnetoresistance ratio (MR ratio) of the vehicle-mounted magnetoresistive sensor elements according to Examples 1 to 3 and Comparative Examples 1 to 3 after 500-hour storage at temperatures ranging from 100° C. to 200° C., an assumed range of ambient temperatures, as compared with the magnetoresistance ratio (MR ratio) before storage. In this measurement, samples prior to heat treatment are used as the GMR elements of the examples and comparative examples.

Any of the samples corresponding to the invented examples exhibits an increased magnetoresistance ratio (MR ratio) after storage within this temperature range as compared with that before storage. In contrast, any of the samples corresponding to the comparative examples exhibits a decreased magnetoresistance ratio (MR ratio) with an increasing temperature, indicating that the heat tolerance markedly varies depending on the composition and thickness of a magnetic layer constituting the GMR element.

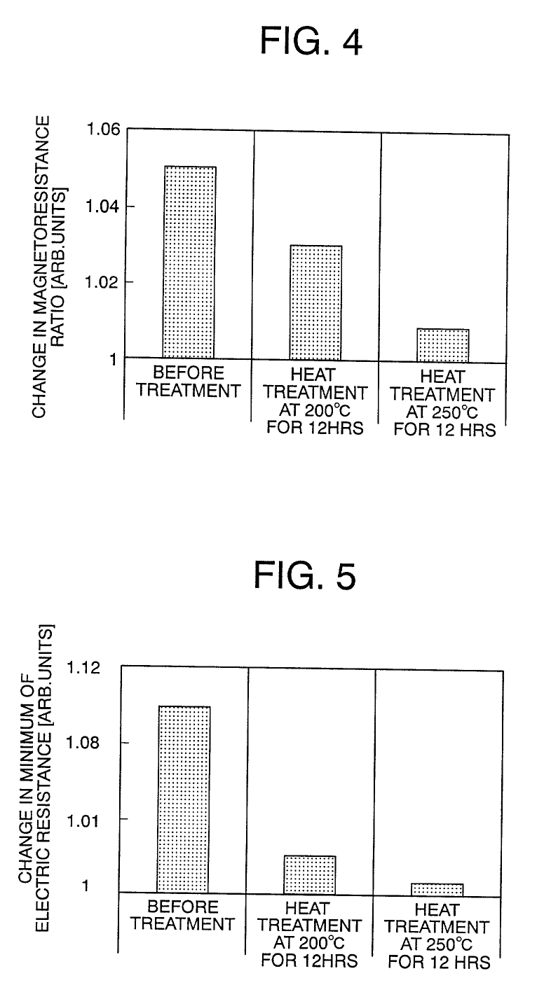

However, the samples corresponding to the invented examples exhibit a significant change in magnetoresistance change and are not preferred from the viewpoint of stability in characteristics, although they have satisfactory heat tolerance. FIG. 4 is a diagram showing a change in magnetoresistance ratio (MR ratio) when a vehicle-mounted magnetoresistive sensor element according to Example 1 is subjected to heat treatment at 200° C. or 250° C., higher than the ambient temperature, and is then stored at 170° C. for 500 hours. In this procedure, the upper limit of the ambient temperature for the vehicle-mounted magnetoresistive element is set at 170° C. as example. FIG. 5 is a diagram showing a change in the minimum of electric resistance after the same treatment as in FIG. 4. In each figure, the effect of heat treatment is shown as compared with a sample not subjected to heat treatment, indicating that the heat treatment stabilizes the characteristics of the GMR element. Additionally, heat treatment at a temperature of equal to or higher than (T+50)° C. is effective, where T (° C.) is the ambient temperature (environmental temperature).

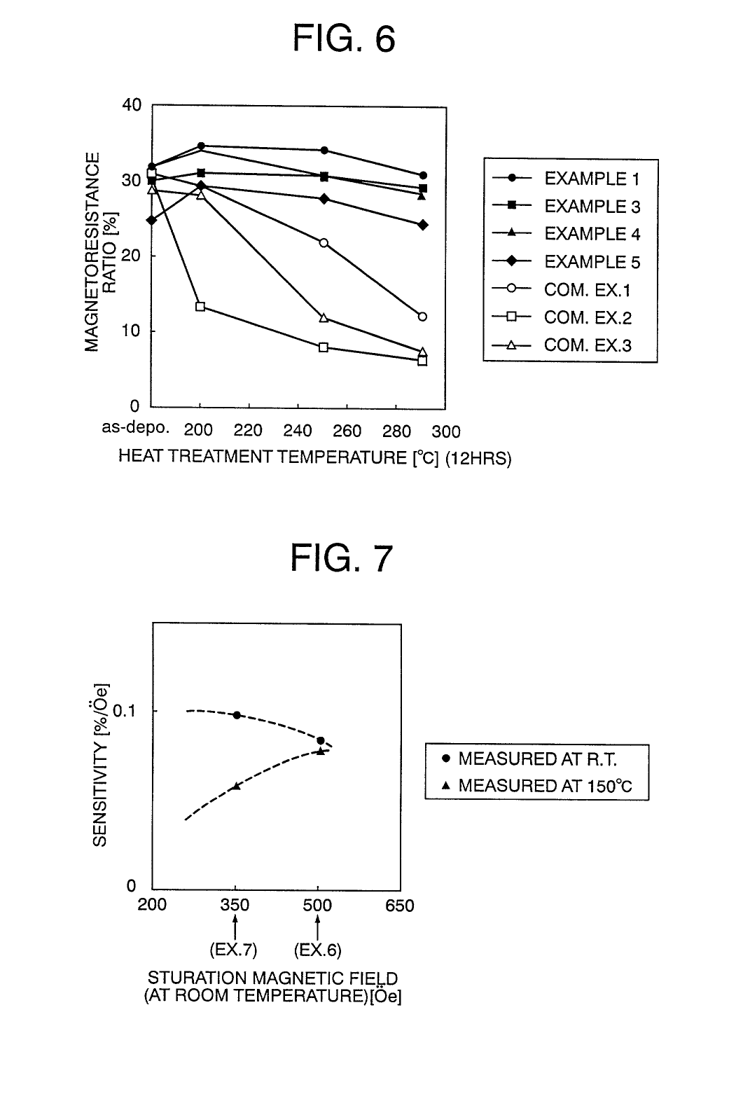

FIG. 6 is a diagram showing changes in magnetoresistance ratio (MR ratio) of vehicle-mounted magnetoresistive sensor elements according to Examples 1 and 3 to 5 and Comparative Examples 1 to 3 after heat treatment at temperatures ranging from 200° C. to 300° C. for 12 hours, as compared with the magnetoresistance ratio (MR ratio) before heat treatment. The magnetoresistance ratio (MR ratio) increases at heat treatment temperatures ranging from 200° C. to 250° C. as compared with that before heat treatment. Specifically, any of the GMR elements according to the invented examples can be subjected to heat treatment at a temperature up to 250° C., i.e., at a temperature equal to or higher than (T+50)° C., when the ambient temperature T (° C.) of vehicle-mounted sensor elements is assumed as from 100° C. to 200° C. However, some types of GMR elements are suitable and others are not suitable for heat treatment at a temperature of higher than 250° C. For example, the GMR elements according to Examples 1 and 3 can be subjected to heat treatment at a temperature of higher than 250° C., but the GMR elements according to Examples 4 and 5 should be preferably subjected to heat treatment at a temperature lower than or equal to 250° C.

### Example 6

A GMR element according to the present example has a structure as shown in FIG. 1 and the materials and atomic compositional ratios of individual layers are as follows. Magnetic layer 2a is composed of Fe_{0.1}Co_{0.9}, nonmagnetic layer 2b is composed of Cu, and buffer layer 3 is composed of Fe_{0.1}Co_{0.9} the same as in magnetic layer 2a. Magnetic layer 2a, nonmagnetic layer 2b and buffer layer 3 each have a thickness of 12 angstroms, 21 angstroms, and 50 angstroms, respectively. The number N of the repeating constitutional units in the GMR element is 10.

In the same manner as in Example 1, this film is patterned, followed by the formation of a protective film such as an Si₃N₄ film thereon and heat treatment at 250° C. for 12 hours.

### Example 7

A GMR element according to the present example has a structure as shown in FIG. 1 and the materials and atomic compositional ratios of individual layers are as follows. Magnetic layer 2a is composed of Fe_{0.1}Co_{0.9}, nonmagnetic layer 2b is composed of Cu, and buffer layer 3 is composed of Fe_{0.1}Co_{0.9} the same as in magnetic layer 2a. Magnetic layer 2a, nonmagnetic layer 2b and buffer layer 3 each have a thickness of 20 angstroms, 21 angstroms, and 50 angstroms, respectively. The number N of the repeating constitutional units in the GMR element is 10.

In the same manner as in Example 1, this film is patterned, followed by the formation of a protective film such as an Si₃N₄ film thereon and heat treatment at 250° C. for 12 hours.

The GMR elements according to Examples 6 and 7 each exhibit a saturation magnetic field at room temperature of 500 Oersteds and 350 Oersteds, respectively. FIG. 7 is a graph showing an example, in which the sensitivities of these GMR elements at room temperature and at a high temperature (150° C.) are plotted against saturation magnetic field, when the operating magnetic field is set in a range from 100 Oersteds to 400 Oersteds. The GMR element according to Example 6 (saturation magnetic field: 500 Oersteds) exhibits an almost equal sensitivity under high temperature conditions to that at room temperature, but the GMR element according to Example 7 (saturation magnetic field: 350 Oersteds) exhibits a decreased sensitivity under high temperature conditions as compared with that at room temperature. However, all the sensitivities of the GMR elements according to these examples are satisfactory as vehicle-mounted magnetoresistive sensor elements.

As thus described, the operation under high temperature conditions varies depending on the magnitude of saturation magnetic field and relates to the shape of the magnetoresistance curve and the range of operating magnetic field. The operation under high temperature conditions, as well as heat tolerance, also plays an important role for the application of GMR elements as vehicle-mounted magnetoresistive sensor elements.

All the GMR elements according to the invented examples show a satisfactory sensitivity under high temperature conditions, as well as at room temperature, at an operating magnetic field of equal to or more than 100 Oersteds. The operating magnetic field may be less than, for example, 100 Oersteds, but it should be preferably high from the viewpoint of ensured resistance against disturbance magnetic field. In contrast, the operating magnetic field should be preferably low from the viewpoint of miniaturization of sensors. It is therefore important to set the operating magnetic field in view of the environment to be applied to thereby yield a high signal-to-noise ratio (SN ratio), and the invented GMR elements can yield a high SN ratio even when a relatively high operating magnetic field is set, and are suitable as vehicle-mounted magnetoresistive sensor elements.

In the above invented examples, the GMR elements are subjected to heat treatment for 12 hours, but the heat treatment time may be shorter or longer than 12 hours. For example, a convenient or appropriate heat treatment time for the production of GMR elements may be set, and similar advantages can be obtained by heat treatment for several hours to ten and several hours.

The invented vehicle-mounted magnetoresistive sensor element includes plural plies of a magnetic layer and plural plies of a nonmagnetic layer, the magnetic layer and the nonmagnetic layer are alternately laminated with each other, the magnetic layer mainly contains Ni, Fe and Co, and the nonmagnetic layer mainly contains Cu, in which the magnetic layer has a composition represented by the following formula: Ni_{(1-x-y)}Fe_{y}Coₓ, where x and y satisfy the following conditions: x≧0.7, y≦0.3 and (1−x−y)≦0.15; and the nonmagnetic layer has a composition represented by the following formula: Cu_{z}A_{(1-z)}, where A is an additional element other than Cu, and z≧0.9; the thickness tm (angstrom) of the magnetic layer and the thickness tn (angstrom) of the nonmagnetic layer satisfy the following conditions: 10<tm<25; and 18<tn<25; and, when a guaranteed storage temperature of the magnetoresistive sensor element is T° C., the magnetoresistive sensor element has been previously subjected to heat treatment at a temperature equal to or higher than T° C. This vehicle-mounted magnetoresistive sensor element is highly resistant against a disturbance magnetic field and has a high sensitivity, i.e., a high SN ratio of output signals, has high heat tolerance, exhibits maintained high SN ratio even under high temperature conditions and is therefore highly reliable. Accordingly, the resulting sensor using the invented element can detect a magnetic field with such a high precision that conventional equivalents cannot achieve. In addition, the tolerance of registration of the sensor can be improved.

In a preferred embodiment, when a unit composed of a laminate of one ply of the magnetic layer and one ply of the nonmagnetic layer is defined as a repeating constitutional unit, the number N of the repeating constitutional units in the magnetoresistive sensor element satisfies the following condition: 10≦N≦40. By this configuration, the reliability of the sensor element under high temperature conditions can be further improved.

In another preferred embodiment, the vehicle-mounted magnetoresistive sensor element preferably further includes a substrate and a buffer layer, which buffer layer is sandwiched between the substrate and the magnetic layer or is sandwiched between the substrate and the nonmagnetic layer, in which the thickness tb (angstrom) of the buffer layer satisfies the following condition: 10<tb<80. By this configuration, the reliability of the sensor element under high temperature conditions can be further improved.

In a preferred embodiment of the vehicle-mounted magnetoresistive sensor element, the heat treatment is performed at a temperature of equal to or higher than (T+50)° C. By this configuration, the reliability of the sensor element under high temperature conditions can be further improved.

In a further preferred embodiment of the vehicle-mounted magnetoresistive sensor element, the heat treatment is performed at a temperature equal to or higher than 200° C. and lower than or equal to 300° C. By this configuration, the reliability of the sensor element under high temperature conditions can be further improved.

Other embodiments and variations will be obvious to those skilled in the art, and this invention is not to be limited to the specific matters stated above.

What is claimed is:

1. A vehicle-mounted magnetoresistive sensor element comprising plural plies of a magnetic layer and plural plies of a nonmagnetic layer, said magnetic layer and said nonmagnetic layer being alternately laminated with each other, said magnetic layer mainly containing Ni, Fe and Co, and said nonmagnetic layer mainly containing Cu,
wherein said magnetic layer has a composition represented by the following formula:
Ni_{(1-x-y)}Fe_{y}Coₓ
where x and y satisfy the following conditions:
x≧0.7, y≦0.3, and (1−x−y)≦0.15;
and said nonmagnetic layer has a composition represented by the following formula:
Cu_{z}A_{(1-z)}
where A is an additional element other than Cu, and z≧0.9;
wherein the thickness tm (angstrom) of said magnetic layer and the thickness tn (angstrom) of said nonmagnetic layer satisfy the following conditions:
10<tm<25, and 18<tn<25;
and wherein, when a guaranteed storage temperature of said magnetoresistive sensor element is T° C., the magnetoresistive sensor element has been previously subjected to heat treatment at a temperature equal to or higher than T° C.

2. A vehicle-mounted magnetoresistive sensor element according to claim 1, wherein when a unit comprising a laminate of one ply of said magnetic layer and one ply of said nonmagnetic layer is defined as a repeating constitutional unit, the number N of said repeating constitutional units in the magnetoresistive sensor element satisfies the following condition:
10≦N≦40

3. A vehicle-mounted magnetoresistive sensor element according to claim 1, further comprising a substrate and a buffer layer, said buffer layer being sandwiched between said substrate and said magnetic layer or being sandwiched between said substrate and said nonmagnetic layer, wherein the thickness tb (angstrom) of said buffer layer satisfies the following condition:
10<tb<80

4. A vehicle-mounted magnetoresistive sensor element according to claim 1, wherein the heat treatment is performed at a temperature of equal to or higher than (T+50)° C.

5. A vehicle-mounted magnetoresistive sensor element according to claim 4, wherein the heat treatment is performed at a temperature equal to or higher than 200° C. and lower than or equal to 300° C.
